(19) United States
(12) Patent Application Publication
(10) Pub. No.: US 2026/0080921 A1
(43) Pub. Date: Mar. 19, 2026

(54) MEMORY SYSTEM AND METHOD

(71) Applicant: Kioxia Corporation, Tokyo (JP)

(72) Inventor: Takayuki AIDA, Kamakura (JP)

(73) Assignee: Kioxia Corporation, Tokyo (JP)

(21) Appl. No.: 19/073,577

(22) Filed: Mar. 7, 2025

(30) Foreign Application Priority Data
Sep. 13, 2024 (JP) 2024-158736

(51) Int. Cl. G11C 7/04; G11C 7/10; G11C 29/52

(52) U.S. Cl. CPC G11C 7/04; G11C 7/1084; G11C 7/1093; G11C 7/1096; G11C 29/52

(57) ABSTRACT

According to one embodiment, in a first write operation, a controller transfers first data to be written to a memory device and causes the memory device to store first data into a memory cell array. In a second write operation, the controller transfers second data to be written to the memory device and acquires the second data from a buffer circuit. The controller determines the number of error bits included in the acquired second data. When the number of error bits is larger than a first threshold value, the controller executes a training operation of adjusting delay time of a delay circuit. When the number of error bits is smaller than the first threshold value, the controller causes the memory device to store, into the memory cell array, the second data having been stored in the buffer circuit, without executing the training operation.

### CROSS-REFERENCE TO RELATED APPLICATIONS

This application is based upon and claims the benefit of priority from Japanese Patent Application No. 2024-158736, filed on Sep. 13, 2024, the entire contents of which are incorporated herein by reference.

### FIELD

Embodiments described herein relate generally to a memory system and a method.

### BACKGROUND

A memory system includes a controller and a memory chip. Data transfer is performed between the controller and the memory chip. In order to speed up the data transfer, it is considered to apply the Un-matched DQS architecture to a reception circuit of the data transfer. According to the Un-matched DQS architecture, in the reception circuit, a delay circuit is provided only in a path of a data strobe signal out of a path of a data signal and the path of the data strobe signal. Then, a timing of the data strobe signal with respect to the data signal is adjusted by adjusting the delay circuit.

The adjustment of the delay circuit is referred to as a training operation.

The delay time of the delay circuit may change depending on various factors such as a temperature change. When the Un-matched DQS architecture is applied, training operations are necessary at a relatively high frequency.

### BRIEF DESCRIPTION OF THE DRAWINGS

FIG. 1 is a diagram illustrating a configuration example of a memory system according to a first embodiment;

FIG. 2 is a diagram illustrating a configuration example of each memory chip according to the first embodiment;

FIG. 3 is a diagram illustrating a circuit configuration of a block according to the first embodiment;

FIG. 4 is a diagram illustrating an example of a configuration of a signal processing circuit as a reception circuit according to the first embodiment;

FIGS. 5A and 5B are diagrams illustrating a training operation according to the first embodiment;

FIG. 6 is a diagram illustrating an example of a latch test operation according to the first embodiment;

FIGS. 7A and 7B are diagrams illustrating an example of the latch test operation according to the first embodiment;

FIG. 8 is a flowchart illustrating an example of an operation of a controller according to the first embodiment;

FIG. 9 is a diagram illustrating an example of a timing of the training operation according to the first embodiment;

FIGS. 10A and 10B are diagrams illustrating an example of operations before and after a latch test operation according to a modification of the first embodiment;

FIG. 11 is a diagram illustrating an example of a timing of a latch test write operation according to a second embodiment; and

FIGS. 12A and 12B constitute a flowchart illustrating an example of an operation of a controller according to the second embodiment.

### DETAILED DESCRIPTION

According to the present embodiment, in general, a memory system includes a memory device and a controller. The memory device includes a first terminal to which a data signal is input, a second terminal to which a data strobe signal is input, a latch circuit, a delay circuit, a memory cell array, and a buffer circuit. The latch circuit is configured to latch, based on the data strobe signal, first data or second data from the data signal. The delay circuit is connected between the second terminal and the latch circuit. The buffer circuit is connected between the memory cell array and the latch circuit. The controller is connected to the memory device via the first terminal and the second terminal. The controller is capable of executing a first write operation and executing a second write operation. The controller is configured to, in the first write operation, transfer the first data to be written to the memory device by using the data signal and the data strobe signal, and causes the memory device to store the first data into the memory cell array. The controller is configured to, in the second write operation, transfer the second data to be written to the memory device by using the data signal and the data strobe signal. The second data is stored in the buffer circuit after being latched by the latch circuit. The controller is further configured to, in the second write operation, acquire the second data from the buffer circuit and determine the number of error bits included in the acquired second data. When the number of error bits is larger than a first threshold value, the controller executes a training operation of adjusting delay time of the delay circuit. When the number of error bits is smaller than the first threshold value, the controller causes the memory device to store, into the memory cell array, the second data having been stored in the buffer circuit, without executing the training operation.

Hereinafter, a memory system and a method according to embodiments are described in detail with reference to the accompanying drawings. Note that the present disclosure is not limited by the embodiments.

### First Embodiment

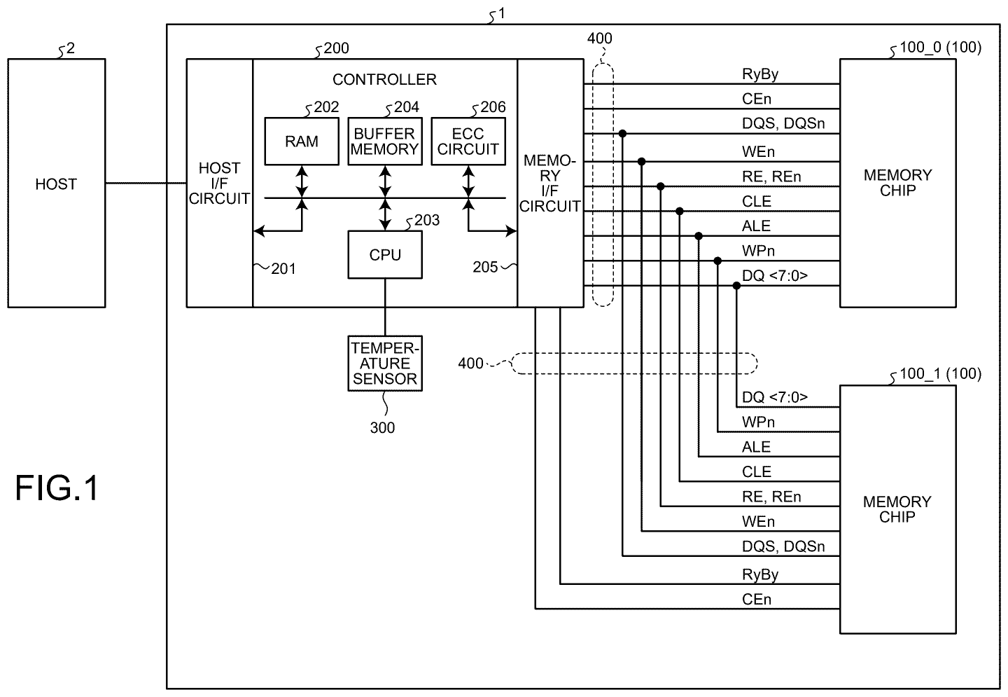

FIG. 1 is a diagram illustrating a configuration example of a memory system according to a first embodiment. As illustrated in FIG. 1, a memory system 1 can be connected to a host 2. The host 2 is, for example, an information processing apparatus such as a server, a personal computer, or a mobile terminal. The memory system 1 functions as an external storage device of the host 2. The host 2 can transmit an access request such as a read request or a write request to the memory system 1.

The memory system 1 includes one or more memory chips 100, a controller 200, and a temperature sensor 300. The memory chip 100 operates based on a command from the controller 200. The memory chip 100 is, for example, a NAND flash memory. The memory system 1 of the present embodiment includes memory chips 100_0 and 100_1 as the one or more memory chips 100. The number of memory chips 100 in the memory system 1 is not limited to two. When the memory system 1 includes a plurality of memory chips 100, these memory chips 100 may be accommodated in one package.

Note that the memory chip 100 is an example of a memory device.

The temperature sensor 300 detects a temperature. The detected value of the temperature by the temperature sensor 300 is used for various pieces of control by a CPU 203 included in the controller 200.

Each memory chip 100 includes a plurality of memory cell transistors and can store data in a nonvolatile manner in these memory cell transistors. The memory chip 100 is connected to the controller 200 by a memory bus 400. The memory bus 400 includes a signal line used for transmission and reception of a data signal, a control signal, and a status signal. The memory chip 100 transfers, for example, an 8-bit wide data signal DQ<7:0> with the controller 200. The bit width of the data signal DQ is not limited to eight bits. In addition to data, a command and an address are transferred as the data signal DQ<7:0>. The memory chip 100 receives a control signal from the controller 200 and transmits a status signal to the controller 200. The status signal includes a ready/busy signal RyBy.

The control signal includes a chip enable signal CEn, a command latch enable signal CLE, an address latch enable signal ALE, a write enable signal WEn, a pair of read enable signals RE and REn, a pair of data strobe signals DQS and DQSn, and a write protect signal WPn. Here, “n” written at the end of a sign of a signal represents that the signal is operated with negative logic. Whether each signal is operated with negative logic or positive logic can be freely designed.

The chip enable signal CEn is a signal that causes a memory chip 100 of an access target to enter an enabled state. The chip enable signal CEn is individually input to each of the two memory chips 100_1 and 100_2. The signals DQ<7:0>, DQS, DQSn, CLE, ALE, WEn, RE, REn, and WPn are commonly input to the two memory chips 100_1 and 100_2. The memory chip 100 that enters the enabled state by the chip enable signal CEn among the two memory chips 100_1 and 100_2 can execute an operation according to a signal input in common.

The pair of data strobe signals DQS and DQSn are signals for instructing a destination to latch data transmitted as the data signal DQ<7:0>. A transfer source of the data signal DQ<7:0> in each of the controller 200 and the memory chip 100 can transmit the pair of data strobe signals DQS and DQSn. Thus, the pair of data strobe signals DQS and DQSn can be transmitted from the controller 200 to the memory chip 100 or can be transmitted from the memory chip 100 to the controller 200.

The command latch enable signal CLE is a signal indicating that the data signal DQ<7:0> is a command. The address latch enable signal ALE is a signal indicating that the data signal DQ<7:0> is an address. The write enable signal WEn is a signal instructing the memory chip 100 to latch a command or an address transmitted as the data signal DQ<7:0>. The pair of read enable signals RE and REn is a signal instructing the memory chip 100 to output the data signal DQ<7:0>. The memory chip 100 can delay the input pair of read enable signals RE and REn and output the delayed read enable signals as the pair of data strobe signals DQS and DQSn. The write protect signal WPn is a signal instructing the memory chip 100 to prohibit the execution of a program operation and an erase operation.

The ready/busy signal RyBy is a signal indicating whether the memory chip 100 is in a ready state (Ry) or a busy state (By). The ready state (Ry) is a state where the memory chip 100 can receive a command from the controller 200.

Note that the configuration of the memory bus 400 is not limited to the above example. As long as the data signal DQ<7:0> and the data strobe signals DQS and DQSn can be transferred, the type and number of signals that can be transferred through the memory bus 400 are any type and number.

Hereinafter, the data strobe signal DQS is described as a representative of the pair of data strobe signals DQS and DQSn, and the description of the data strobe signal DQSn is omitted. The data signal DQ<7:0> is abbreviated as the data signal DQ.

The controller 200 can command various operations to the memory chip 100 based on a request from the host 2 or the like.

The controller 200 includes a host interface (I/F) circuit 201, a random access memory (RAM) 202, the CPU 203, a buffer memory 204, a memory interface (I/F) circuit 205, and an error correction code (ECC) circuit 206. The controller 200 may be configured as, for example, a system-on-a-chip (SoC). The controller 200 may be configured as a field-programmable gate array (FPGA) or an application specific integrated circuit (ASIC). The controller 200 may be configured with a plurality of chips. Each function of the controller 200 may be realized by a processor that executes software (firmware), a dedicated hardware circuit, or a combination thereof.

The host interface (I/F) circuit 201 is connected to the host 2 via a bus conforming to, for example, the Serial Advanced Technology Attachment (SATA) standard, the Serial Attached SCSI (SAS) standard, or the Peripheral Components Interconnect (PCI) Express (registered trademark) standard. The host interface circuit 201 manages communication between the controller 200 and the host 2.

The memory interface circuit 205 is electrically connected to each memory chip 100 via the memory bus 400. The memory interface circuit 205 manages communication between the controller 200 and the memory chip 100.

The CPU 203 controls the operation of the controller 200.

The RAM 202 is used as a work area of the CPU 203. The buffer memory 204 temporarily stores data to be transmitted to the memory chip 100 and data output from the memory chip 100. The RAM 202 and the buffer memory 204 may be configured with, for example, a dynamic random access memory (DRAM), a static random access memory (SRAM), or a combination thereof. The RAM 202 may be provided outside the controller 200.

The ECC circuit 206 performs encoding using an error correction code on data to be transmitted to the memory chip 100. In addition, the ECC circuit 206 decodes the encoded data received from the memory chip 100 and detects and corrects an error in the data. The ECC circuit 206 may be provided in the memory interface circuit 205.

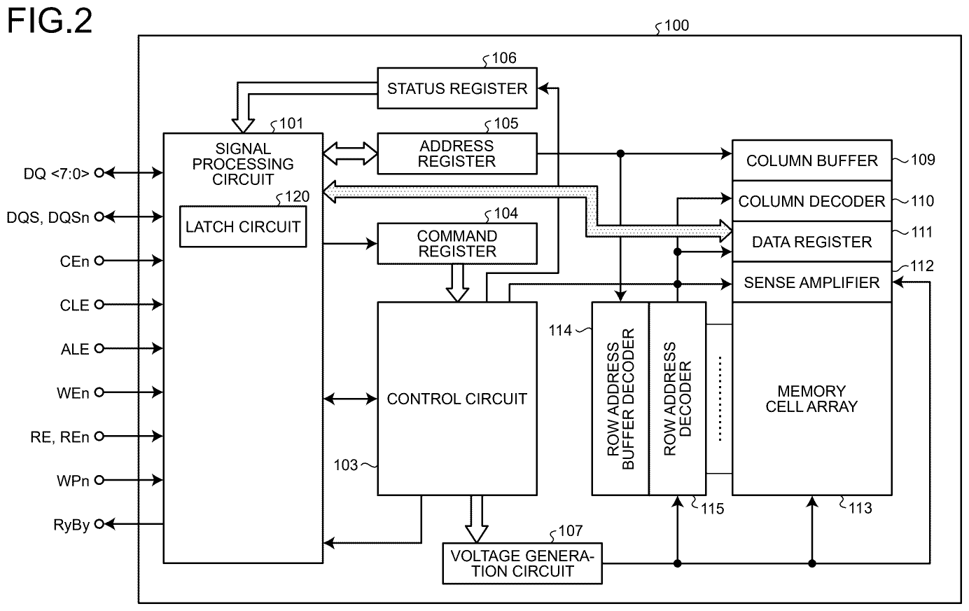

FIG. 2 is a diagram illustrating a configuration example of each memory chip 100 according to the first embodiment.

The memory chip 100 includes a signal processing circuit 101, a control circuit 103, a command register 104, an address register 105, a status register 106, a voltage generation circuit 107, a column buffer 109, a column decoder 110, a data register 111, a sense amplifier 112, a memory cell array 113, a row address buffer decoder 114, and a row address decoder 115.

The signal processing circuit 101 includes a latch circuit 120. The latch circuit 120 latches the data signal DQ transferred from the controller 200 at a toggle timing of the data strobe signal DQS transferred from the controller 200.

In addition, the signal processing circuit 101 receives a control signal. The signal processing circuit 101 determines whether the data signal DQ transferred from controller 200 is a command, an address, or data, based on the received control signal.

The signal processing circuit 101 distributes and stores the command, the address, and the data, which are transferred as the data signal DQ and latched into the latch circuit 120, in the command register 104, the address register 105, and the data register 111, respectively.

The address stored in the address register 105 includes a row address and a column address. The row address is sent to the row address buffer decoder 114. The column address is sent to the column buffer 109.

The control circuit 103 is a state transition circuit (or a state machine) that transitions a state based on a control signal. The control signal is input to the control circuit 103 via the signal processing circuit 101. The control circuit 103 controls the entire operation of the memory chip 100 based on various control signals and commands stored in the command register 104.

The control circuit 103 generates status information indicating a state of operation control, a result of operation control, or the like and stores the status information in the status register 106. The control circuit 103 outputs the status information stored in the status register 106 in response to a status read command from the controller 200.

The signal processing circuit 101 transitions the state of the ready/busy signal RyBy between the ready state (Ry) and the busy state (By) under the control of the control circuit 103.

The memory cell array 113 has a configuration in which a plurality of memory cell transistors are arranged. Each of the memory cell transistors is connected to a bit line BL and a word line WL. The memory cell array 113 stores data and the like received from the host 2.

The memory cell array 113 includes a plurality of blocks BLK. All data stored in the block BLK is collectively erased. An operation of erasing all data stored in the block BLK is referred to as an erase operation.

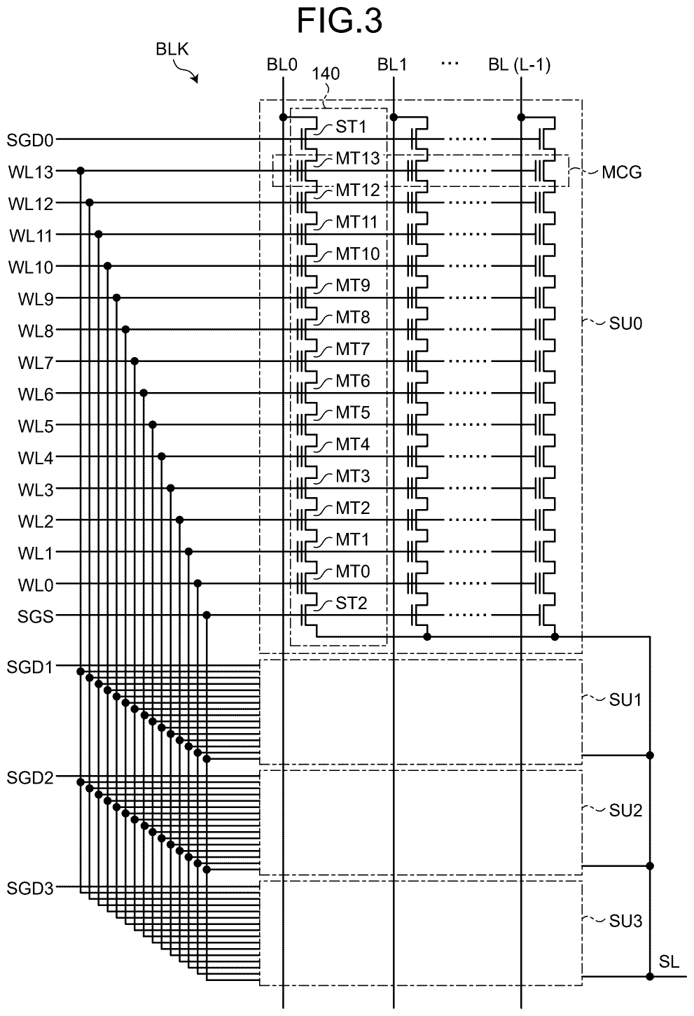

FIG. 3 is a diagram illustrating a circuit configuration of the block BLK according to the first embodiment. Each block BLK has the same configuration. The block BLK includes, for example, four string units SU0 to SU3. Each string unit SU includes a plurality of memory strings 140.

Each of the memory strings 140 includes, for example, fourteen (14) memory cell transistors MT (MT0 to MT13) and select transistors ST1 and ST2. The fourteen memory cell transistors MT (MT0 to MT13) are connected in series between the source of the select transistor ST1 and the drain of the select transistor ST2. The number of memory cell transistors MT in the memory string 140 is not limited to fourteen. The memory cell transistor MT includes a control gate and a charge storage layer and stores data in a nonvolatile manner. The memory cell transistor MT may be a metal-oxide-nitride-oxide-silicon (MONOS) type using an insulating film for the charge storage layer or may be a floating-gate (FG) type using a conductive film for the charge storage layer.

The gates of the select transistors ST1 in the string units SU0 to SU3 are connected to select gate lines SGD0 to SGD3, respectively. The gates of the select transistors ST2 in the string units SU0 to SU3 are commonly connected to, for example, a select gate line SGS. Alternatively, the gates of the select transistors ST2 in the string units SU0 to SU3 may be connected to select gate lines SGS0 to SGS3 (not illustrated) different for each string unit SU. The control gates of the memory cell transistors MT0 to MT13 in the same block BLK are commonly connected to the word lines WL0 to WL13, respectively.

The drains of the select transistors ST1 of the memory strings 140 in the string unit SU are connected to different bit lines BL (BL0 to BL(L-1), where L is a natural number of 2 or larger). In addition, the bit line BL commonly connects one memory string 140 in each string unit SU among the blocks BLK. Moreover, the source of each select transistor ST2 is commonly connected to a source line SL.

The string unit SU is a set of memory strings 140 connected to different bit lines BL and connected to the same select gate line SGD. The block BLK is a set of the string units SU that share the word line WL. The memory cell array 113 is a set of the blocks BLK that share the bit line BL.

When a command to write data is given from the controller 200, the threshold voltage of the memory cell transistor MT is set to a state corresponding to the data.

This operation is referred to as a program operation. In addition, when a command to read data is given from the controller 200, a state of the threshold voltage of the memory cell transistor MT is determined, and the determined state is converted into data. This operation is referred to as a sense operation.

The program operation and the sense operation are collectively performed on the memory cell transistors MT connected to one word line WL in one string unit SU. A group of the memory cell transistors MT selected collectively during the program operation and the sense operation is referred to as a memory cell group MCG. Then, a group of 1-bit storage areas of each of the memory cell transistors MT in which data is written by the program operation to one memory cell group MCG (or from which data is read by the sense operation) is referred to as a page.

Note that the number of pages provided by one memory cell group MCG depends on the number of bits of data stored in each memory cell transistor MT. When the number of bits of data stored in each memory cell transistor MT is K (where K is an integer of 1 or larger), one memory cell group MCG can provide K pages. Hereinafter, as an example, one memory cell group MCG provides three pages. Data to be stored in one of the three pages provided by the memory cell group MCG is referred to as lower page data. Data to be stored in another page is referred to as middle page data. Data to be stored in the remaining one page is referred to as upper page data.

The description refers back to FIG. 2.

Data to be written by a program operation is stored in the data register 111. In addition, data read from the memory cell array 113 by a sense operation is stored in the data register 111.

Note that the data register 111 is an example of a buffer circuit, which is connected between the signal processing circuit 101 and the memory cell array 113.

Data to be written, which is transferred from the controller 200, is latched by the latch circuit 120 of the signal processing circuit 101 and stored in the data register 111. Then, the data to be written, which is stored in the data register 111, is stored in the memory cell array 113 by a program operation. An operation in which, the controller 200 transfers data to be written to the memory chip 100, and the memory chip 100 stores the data to be written in the data register 111 via the latch circuit 120, is referred to as a data-in operation. Hereinafter, an operation including the data-in operation and the program operation is referred to as a write operation.

Data read from the memory cell array 113 by the sense operation is stored in the data register 111. Some of or all pieces of the data stored in the data register 111 are transferred to the controller 200 via the signal processing circuit 101. An operation of transferring data stored in the data register 111 to the controller 200 is referred to as a data-out operation. In addition, an operation including the sense operation and the data-out operation is referred to as a read operation.

The voltage generation circuit 107 generates various voltages necessary for access (e.g., the program operation, the sense operation, and the erase operation) to the memory cell array 113 based on the power input to a Vcc terminal (not illustrated).

Then, the voltage generation circuit 107 supplies the generated voltage to each of the sense amplifier 112, the memory cell array 113, and the row address decoder 115.

The row address decoder 115, the column decoder 110, and the sense amplifier 112 execute access (e.g., the program operation, the sense operation, and the erase operation) to the memory cell array 113 under the control of the control circuit 103.

Next, a more detailed configuration of the signal processing circuit 101 is described. The signal processing circuit 101 has a function as a reception circuit that receives the data signal DQ.

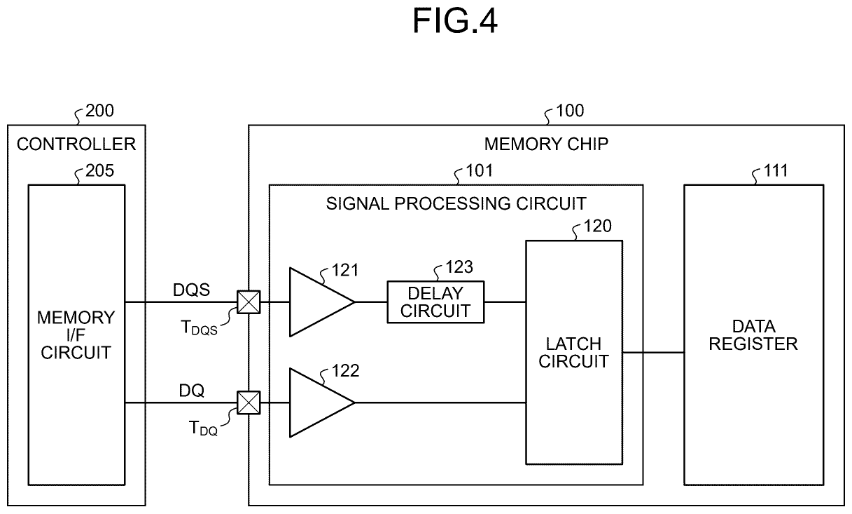

FIG. 4 is a diagram illustrating an example of a configuration of the signal processing circuit 101 as a reception circuit according to the first embodiment. As illustrated in FIG. 4, the signal processing circuit 101 includes a driver 121, a driver 122, and a delay circuit 123 in addition to the latch circuit 120.

The memory chip 100 includes a terminal T_{DQ} to which the data signal DQ is input from the memory interface circuit 205 and a terminal T_{DQS} to which the data strobe signal DQS is input from the memory interface circuit 205. The terminal T_{DQ} is an example of a first terminal. The terminal T_{DQS} is an example of a second terminal.

The driver 121 and the delay circuit 123 are connected between the terminal T_{DQS} and the latch circuit 120. The data strobe signal DQS input to the terminal T_{DQS} is input to the latch circuit 120 via the driver 121 and the delay circuit 123 in this order.

The driver 122 is connected between the terminal T_{DQ} and the latch circuit 120. The data signal DQ input to the terminal T_{DQ} is input to the latch circuit 120 via the driver 122. The latch circuit 120 latches data from the data signal DQ input thereto based on the data strobe signal DQS input thereto.

As described above, the signal processing circuit 101 as a reception circuit has a configuration of the Un-matched DQS architecture in which the delay circuit 123 is provided only in the path of the data strobe signal DQS out of the path of the data signal DQ and the path of the data strobe signal DQS.

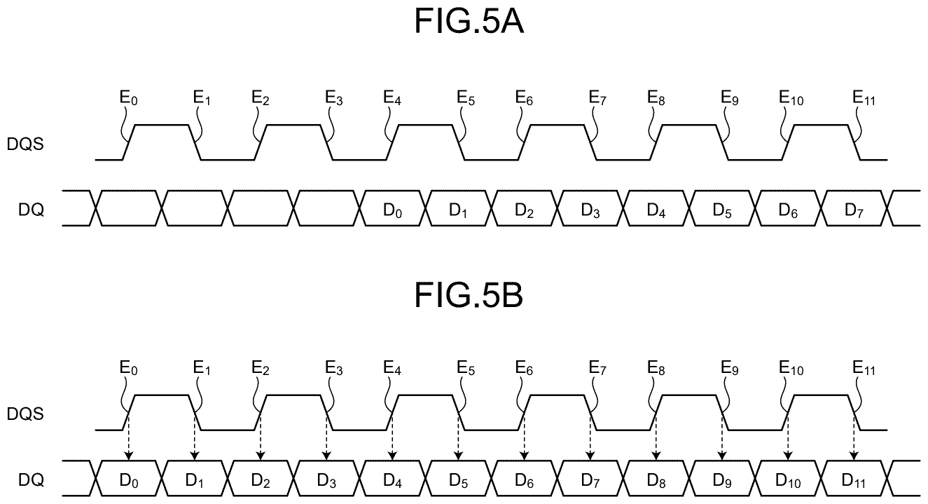

The delay time of the delay circuit 123 is adjusted by a training operation. The training operation according to the first embodiment is described with reference to FIGS. 5A and 5B.

FIG. 5A illustrates waveforms of the data strobe signal DQS and the data signal DQ at the boundary (namely, at the terminals T_{DQS} and T_{DQ}) of the memory chip 100. FIG. 5B illustrates waveforms of the data strobe signal DQS and the data signal DQ at the latch circuit 120.

Here, it is assumed that the latch circuit 120 is configured to latch data from the data signal DQ at the timing of both a rising edge and a falling edge of the data strobe signal DQS. Alternatively, the latch circuit 120 may be configured to latch data at the timing of either the rising edge or the falling edge of the data strobe signal DQS.

The controller 200 toggles the data strobe signal DQS by the number of times corresponding to the total size of data transferred as the data signal DQ so that the data transferred as the data signal DQ can be latched. Accordingly, among the data transferred as the data signal DQ, an edge E for latching the x-th transferred 8-bit data D (denoted as data Dₓ, where x is a numerical value) from the head, is naturally determined. An edge of the data strobe signal DQS for latching the data Dₓ is referred to as an edge Eₓ.

In the example illustrated in FIG. 5A, the timings of the edges E₀, E₁, E₂, and the like of the data strobe signal DQS are significantly earlier than the transfer timings of the data D₀, D₁, D₂, and the like. Therefore, the reception circuit cannot completely latch all the data D transferred as the data signal DQ.

The delay circuit 123 delays the data strobe signal DQS so that the latch circuit 120 can latch all the data D transferred as the data signal DQ. In the training operation, the delay time of the data strobe signal DQS is adjusted so that the timing of each of the edges E₀, E₁, E₂, and the like of the data strobe signal DQS coincides with the timing of the center of the eye pattern of the corresponding data D. As a result, as illustrated in FIG. 5B, in the latch circuit 120, the transfer timing of each data D coincides with the timing of the corresponding edge E, and the latch circuit 120 can latch each data D.

As described above, the delay time of the delay circuit 123 may vary depending on factors such as the temperature around the delay circuit 123. Thus, the timing of the data strobe signal DQS with respect to the data signal DQ may be changed by a temperature change from the ideal timing illustrated in FIG. 5B. The number of error bits in the transferred data increases as the timing of the data strobe signal DQS with respect to the data signal DQ deviates from the ideal timing illustrated in FIG. 5B, for example due to the temperature change. Then, for example, when data including the number of error bits exceeding the correction capability of the ECC circuit 206 is stored in the memory cell array 113, the controller 200 cannot correctly read the data. In order to prevent such a situation, the further training operation is necessary even after the training operation is once completed.

With respect to the Un-matched DQS architecture, some standards define a reference to the further training operation. For example, according to Toggle 5.1 and subsequent standards defined by the JEDEC Semiconductor Technology Association (Joint Electron Device Engineering Council Solid State Technology Association), it is recommended to perform the training operation for each temperature change of 25 degrees Celsius.

In the training operation, data transfer between the controller 200 and the memory chip 100 is performed many times. During the training operation, there is a period of time during which the controller 200 cannot execute either the write operation or the read operation on the memory chip 100. Therefore, the performance of the memory system 1 decreases according to the execution frequency of the training operation.

In the first embodiment, even if the controller 200 detects that the temperature change amount exceeds a predetermined value (for example, 25 degrees Celsius), if the operation of the reception circuit satisfies a predetermined criterion, the training operation is skipped. The predetermined criterion is, for example, that the degree of error occurring when data is latched by the latch circuit 120 is within an allowable range. The controller 200 detects the degree of an error that occurs when data is latched by the latch circuit 120 and determines whether to skip the training operation according to the detection result. An operation of detecting a degree of an error occurring when data is latched by the latch circuit 120 is referred to as a latch test operation.

In order to efficiently execute the latch test operation, the controller 200 uses data to be written that is transferred from the controller 200 to the memory chip 100 during the write operation.

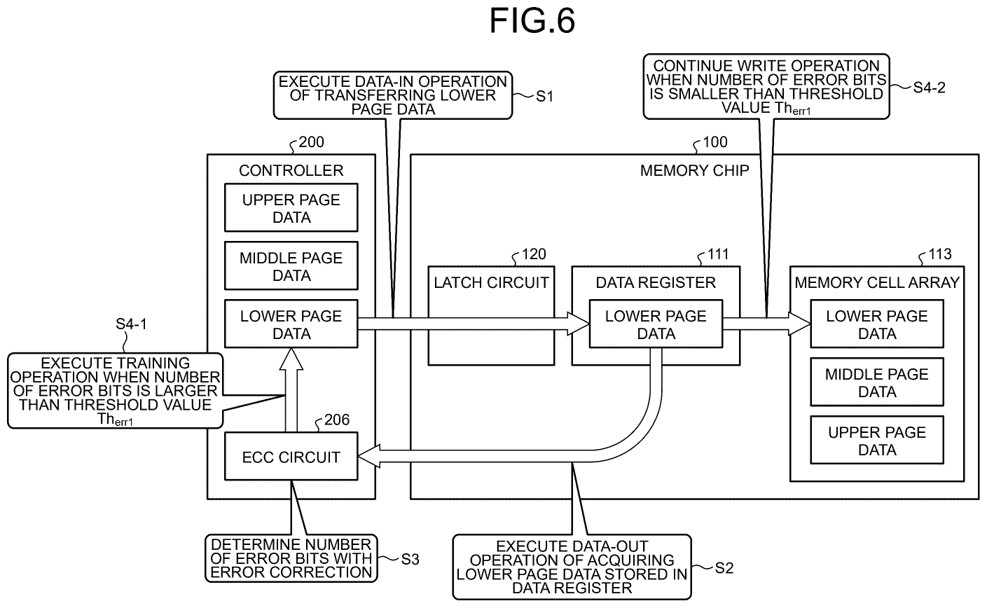

FIG. 6 is a diagram illustrating an example of the latch test operation according to the first embodiment.

The controller 200 executes the data-in operation of transferring lower page data among the lower page data, the middle page data, and the upper page data to be stored in the memory chip 100 (S1).

In the memory chip 100, the lower page data transferred as the data signal DQ from the controller 200 is latched by 8 bits by the latch circuit 120 based on the data strobe signal DQS, and the lower page data latched by 8 bits is sequentially stored in the data register 111.

Subsequently, the controller 200 executes the latch test operation. The controller 200 executes the data-out operation of acquiring the lower page data stored in the data register 111 (S2). Then, the controller 200 executes error correction with the ECC circuit 206 on the lower page data acquired from the memory chip 100 by the data-out operation. Then, the controller 200 determines the number of errors corrected in the ECC circuit 206, namely, the number of error bits (S3).

When the number of error bits is larger than a threshold value Thₑᵣᵣ₁, the controller 200 executes a training operation (S4-1). A method of setting the threshold value Thₑᵣᵣ₁ is any method. However, for example, a value that does not exceed the upper limit value of the number of error bits on which the error correction by the ECC circuit 206 can be performed (i.e., the correction capability of the ECC circuit 206) is set as the threshold value Thₑᵣᵣ₁.

When the number of error bits is smaller than the threshold value Thₑᵣᵣ₁, the controller 200 skips the training operation and continues the write operation (S4-2).

The controller 200 executes the data-in operation of transferring the middle page data and the upper page data without executing the data-in operation of transferring the lower page data again, and causes the memory chip 100 to execute the program operation of the lower page data, the middle page data, and the upper page data.

Processing when the number of error bits is equal to the threshold value Thₑᵣᵣ₁ may be any processing. Hereinafter, when the number of error bits is equal to the threshold value Thₑᵣᵣ₁, the same processing as that when the number of error bits is smaller than the threshold value Thₑᵣᵣ₁ is executed.

A series of operations described with reference to FIG. 6 is referred to as a latch test write operation. A write operation that does not involve a latch test operation and includes a data-in operation and a program operation is referred to as a normal write operation.

The normal write operation is an example of a first write operation. The latch test write operation is an example of a second write operation. The threshold value Thₑᵣᵣ₁ is an example of a first threshold value.

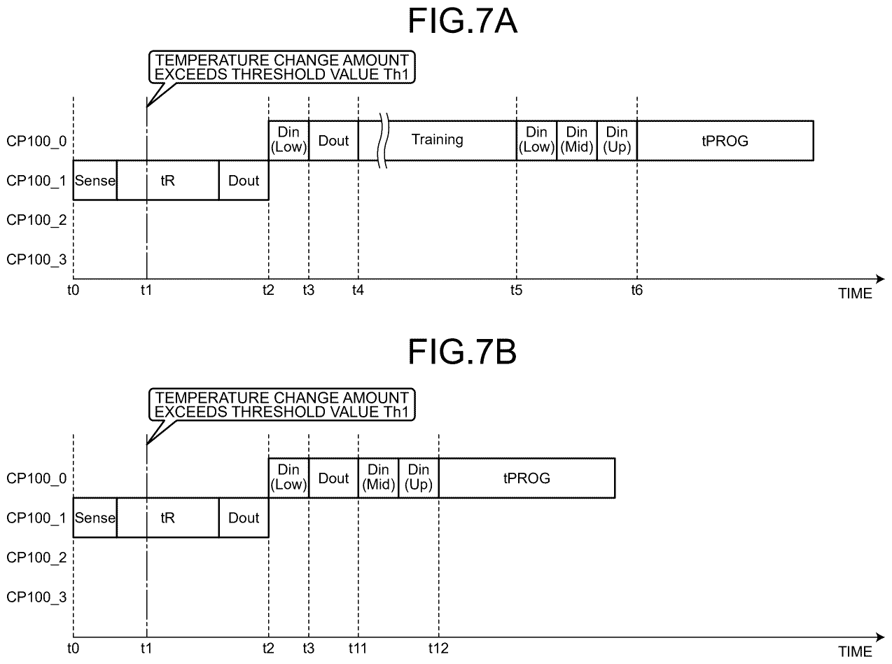

FIGS. 7A and 7B are diagrams illustrating an example of the latch test operation according to the first embodiment. Note that, in the example illustrated in FIGS. 7A and 7B, it is assumed that four memory chips 100_0, 100_1, 100_2, and 100_3 are connected to the memory bus 400. In addition, in FIGS. 7A, 7B, and subsequent figures, the memory chip may be abbreviated as CP. The horizontal axes in FIGS. 7A and 7B indicate time.

FIG. 7A illustrates an operation when a result that the number of error bits is larger than the threshold value Thₑᵣᵣ₁ is obtained by the latch test operation. The read operation for the memory chip 100_1 is executed in a period from time t0 to time t2.

The controller 200 executes, on the memory chip 100_1, transfer of a command for instructing a sense operation (Sense), standby for a period tR, and a data-out operation (Dout). The period tR indicates a period of time for which the sense operation is being executed in the memory chip 100.

When a temperature condition is satisfied, namely, for example, the temperature change amount exceeds a threshold value Th1 (for example, 25 degrees Celsius), and execution of the write operation on a certain memory chip 100 is scheduled at the time t1, the controller 200 executes the latch test operation at the time of the write operation on the certain memory chip 100. In the example illustrated in FIGS. 7A and 7B, the latch test operation is executed at the time of the write operation on the memory chip 100_0.

Specifically, the controller 200 first executes a data-in operation (Din (Low)) for transferring lower page data (time t2). Subsequently, the controller 200 executes a data-out operation (Dout) for acquiring the lower page data that has been latched by the latch circuit 120 and stored in the data register 111 (time t3). The controller 200 executes error correction on the lower page data acquired by the data-out operation and determines the number of error bits. Then, the controller 200 compares the number of error bits with the threshold value Thₑᵣᵣ₁. In the example of FIG. 7A, the number of error bits is larger than the threshold value Thₑᵣᵣ₁, and the controller 200 performs a training operation (Training) (time t4).

When the training operation is completed (time t5), the controller 200 executes the data-in operation (Din (Low)) of transferring the lower page data, the data-in operation (Din (Mid)) of transferring middle page data, and the data-in operation (Din (Up)) of transferring upper page data, in this order. Then, the controller 200 causes the memory chip 100_0 to execute a program operation of storing the lower page data, the middle page data, and the upper page data into one memory cell group MCG (time t6).

A period tPROG indicates a period of time for which the program operation is executed in the memory chip 100.

FIG. 7B illustrates an operation when a result that the number of error bits is equal to or smaller than the threshold value Thₑᵣᵣ₁ is obtained by the latch test operation. The same operation as FIG. 7A is executed until the time t3. The controller 200 executes error correction on the lower page data acquired by the data-out operation (Dout) at the time t3 and determines the number of error bits. Then, the controller 200 compares the number of error bits with the threshold value Thₑᵣᵣ₁. In the example of FIG. 7B, the number of error bits is equal to or smaller than the threshold value Thₑᵣᵣ₁, and the controller 200 continues the write operation. That is, the controller 200 executes the data-in operation (Din (Mid)) of the middle page data and the data-in operation (Din (Up)) of the upper page data (time t11). Then, the controller 200 causes the memory chip 100_0 to execute a program operation of storing the lower page data, the middle page data, and the upper page data into one memory cell group MCG (time t12).

In this manner, the controller 200 uses data to be written, which is transferred to the memory chip 100, to execute the latch test operation. Thus, the controller 200 is not necessary to transfer data dedicated to the latch test operation to the memory chip 100 separately from the data to be written. Therefore, efficiency of the latch test operation is improved.

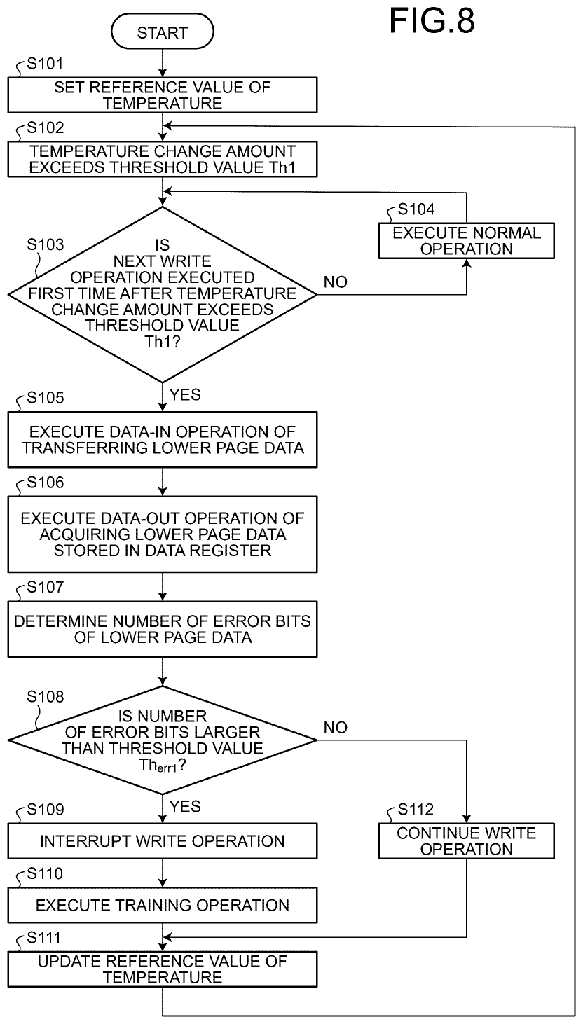

FIG. 8 is a flowchart illustrating an example of the operation of the controller 200 according to the first embodiment. Note that, in the description of FIG. 8, the read operation and the erase operation are not referred to. The read operation and the erase operation are normally executed. A series of operations illustrated in FIG. 8 is executed for each memory chip 100.

First, the controller 200 sets a reference value of temperature (S101). In step S101, the controller 200 acquires a detected value of a temperature from the temperature sensor 300 and sets the acquired detected value as the reference value.

The controller 200 monitors the temperature change amount from the reference value, which is the amount of change in temperature from the reference value, in order to detect that the temperature change amount from the reference value exceeds the predetermined threshold value Th1. The controller 200 acquires a detected value of a temperature from the temperature sensor 300, calculates a temperature change amount based on the acquired detected value, and compares the temperature change amount, which is obtained by the calculation, with the threshold value Th1, for example, periodically.

The threshold value Th1 is set in advance. According to the above-noted Toggle 5.1 and subsequent standards, the threshold value Th1 is 25 degrees Celsius.

The threshold value Th1 may be settable, for example, from the host 2. Note that the threshold value Th1 is an example of a second threshold value.

Hereinafter, the temperature change amount from the reference value is simply referred to as a temperature change amount.

When the temperature change amount exceeds the threshold value Th1 (S102), the controller 200 determines whether the write operation to be executed next is a write operation executed for the first time after the temperature change amount exceeds the threshold value Th1 (S103).

When the temperature change amount does not exceed the threshold value Th1, the controller 200 may execute a normal write operation as the write operation. Note that the processing when the temperature change amount reaches the threshold value Th1 but does not exceed the threshold value Th1 is not limited thereto. When the temperature change amount reaches the threshold value Th1, the control may transition to step S103.

When the write operation to be executed next is not a write operation executed for the first time after the temperature change amount exceeds the threshold value Th1 (S103: No), the controller 200 normally executes the operation (S104). Then, the control transitions to step S103.

When the write operation to be executed next is a write operation executed for the first time after the temperature change amount exceeds the threshold value Th1 (S103: Yes), the controller 200 executes the latch test write operation.

The controller 200 first executes the data-in operation of transferring lower page data (S105). Then, in step S106, the controller 200 executes the data-out operation of acquiring the lower page data that is transferred to the memory chip 100 by the data-in operation and stored in the data register 111 of the memory chip 100.

The controller 200 determines the number of error bits of the lower page data acquired from the memory chip 100 (S107). Then, the controller 200 compares the number of error bits with the threshold value Thₑᵣᵣ₁.

When the number of error bits is larger than the threshold value Thₑᵣᵣ₁ (S108: Yes), the controller 200 interrupts the write operation (S109) and executes the training operation (S110). Along with the execution of the training operation, in step S111, the controller 200 updates the reference value of the temperature change by a method similar to that in step S101, and the control transitions to step S102.

When the number of error bits is not larger than the threshold value Thₑᵣᵣ₁ (S108: No), the controller 200 continues the write operation (S112). Then, the control transitions to step S111. That is, in step S111, the controller 200 updates the reference value of the temperature change by the same method as step S101.

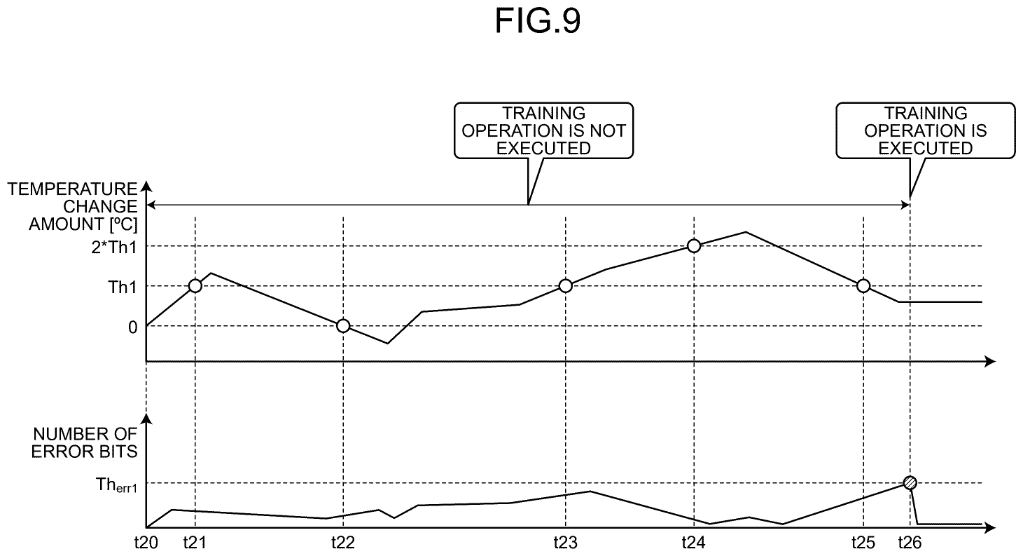

FIG. 9 is a diagram illustrating an example of a timing of the training operation according to the first embodiment. FIG. 9 illustrates temporal transitions of the temperature change amount and the number of error bits obtained when the latch test operation is executed.

At time t20, for example, the reference value of the temperature is set by the processing illustrated as step S101 of FIG. 8. Thereafter, for example, even when the temperature change amount exceeds the threshold value Th1, the training operation is not executed unless the number of error bits becomes larger than the threshold value Thₑᵣᵣ₁ in the latch test operation. In the example illustrated in FIG. 9, the temperature change amount from the reference value of the temperature set at time t20 exceeds the threshold value Th1 at the time t21. Accordingly, at the time t21, the latch test operation and the update of the reference value of the temperature are executed (for example, as illustrated as step S111 in FIG. 8). However, at the time t21, the number of error bits is equal to or smaller than the threshold value Thₑᵣᵣ₁. Therefore, the training operation is not executed at the time t21. Similarly, the temperature change amount from the reference value of the temperature updated at each of the times t21 to t25 exceeds the threshold value Th1 at each of the times t22 to t26. Accordingly, at each of the times t22 to t26, the latch test operation and the update of the reference value of the temperature are executed (for example, as illustrated as step S111 in FIG. 8). However, in each of the times t22 to t25, the number of error bits is equal to or smaller than the threshold value Thₑᵣᵣ₁. Therefore, the training operation is not executed in the period from the time t22 to the time t25. At the time t26, the number of error bits becomes larger than the threshold value Thₑᵣᵣ₁, so that the training operation is executed.

A technique to be compared with the embodiment is described. The technique to be compared with the embodiment is referred to as a comparative example. According to the comparative example, the training operation in the reception circuit is executed every time the temperature change amount exceeds the threshold value Th1. In the comparative example, according to the example of FIG. 9, the training operation is executed at each timing of the time t21, t22, t23, t24, and t25.

Meanwhile, as described above, according to the first embodiment, the training operation is not executed in the period from the time t21 to the time t25, and the training operation is executed at the time t26. Thus, according to the first embodiment, the execution frequency of the training operation is reduced as compared with the comparative example.

As described above, according to the first embodiment, the memory chip 100 includes the signal processing circuit 101, the data register 111 which is a buffer circuit, and the memory cell array 113. The signal processing circuit 101 includes the latch circuit 120 and the delay circuit 123, and the delay circuit 123 is connected between the terminal T_{DQS} and the latch circuit 120. The controller 200 monitors the temperature change amount based on the detected value of the temperature output from the temperature sensor 300. When the temperature change amount is smaller than the threshold value Th1, the controller 200 executes the normal write operation. When the temperature change amount exceeds the threshold value Th1, the controller 200 executes the latch test write operation in a write operation executed for the first time after the temperature change amount exceeds the threshold value Th1.

In the latch test write operation, the controller 200 executes the data-in operation and the latch test operation of acquiring data to be written, which is latched into the latch circuit 120 by the data-in operation and stored in the data register 111, and determines the number of error bits in the acquired data. When the number of error bits is larger than the threshold value Thₑᵣᵣ₁, the controller 200 performs the training operation. When the number of error bits is smaller than the threshold value Thₑᵣᵣ₁, the controller 200 continues the write operation (namely, executes the program operation) without executing the training operation.

Therefore, the execution frequency of the training operation is reduced, and the latch test operation for determining whether to skip the training operation is efficiently executed. As a result, performance decrease of the memory system 1 due to the training operation is prevented.

### Modification

The data used in the latch test operation is not limited to data first transferred to the memory chip 100 (namely, lower page data) in the write operation. As a modification, an example in which the latch test operation is executed using data finally transferred to the memory chip 100 (namely, upper page data) in the write operation is described.

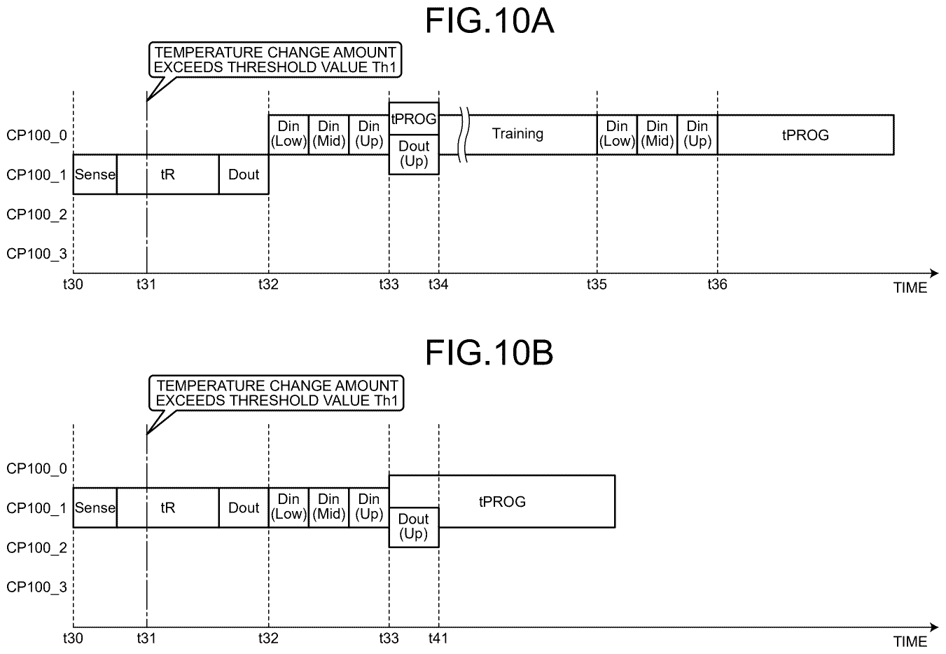

FIGS. 10A and 10B are diagrams illustrating an example of operations before and after the latch test operation according to the modification of the first embodiment. Note that, in the example illustrated in FIGS. 10A and 10B, it is assumed that four memory chips 100_0, 100_1, 100_2, and 100_3 are connected to the memory bus 400. The horizontal axes in FIGS. 10A and 10B indicate time.

FIG. 10A illustrates an operation when a result that the number of error bits is larger than the threshold value Thₑᵣᵣ₁ is obtained by the latch test operation. First, the read operation for the memory chip 100_1 is executed in a period from time t30 to time t32.

At time t31, the temperature change amount exceeds the threshold value Th1. In response to this, at time t32, the write operation into the memory chip 100_0 is started.

Specifically, the controller 200 executes the data-in operation (Din (Low)) of transferring lower page data, the data-in operation (Din (Mid)) of transferring middle page data, and the data-in operation (Din (Up)) of transferring upper page data, in this order (time t32).

Subsequently, the controller 200 causes the memory chip 100_0 to start a program operation of storing the lower page data, the middle page data, and the upper page data into one memory cell group MCG (time t33). Further, the controller 200, which causes the memory chip 100 to start the program operation, executes a data-out operation (Dout (Up)) of acquiring the upper page data that is latched by the latch circuit 120 and stored in the data register 111. The controller 200 executes error correction on the upper page data acquired by the data-out operation and determines the number of error bits. Then, the controller 200 compares the number of error bits with the threshold value Thₑᵣᵣ₁.

In the example of FIG. 10A, it is assumed that the number of error bits is larger than the threshold value Thₑᵣᵣ₁. Therefore, the controller 200 causes the memory chip 100 to suspend the program operation and performs the training operation (time t34).

When the training operation is completed (time t35), the controller 200 executes the data-in operation (Din (Low)) of transferring the lower page data, the data-in operation (Din (Mid)) of transferring the middle page data, and the data-in operation (Din (Up)) of transferring the upper page data, in this order. Then, the controller 200 causes the memory chip 100_0 to execute a program operation of storing the lower page data, the middle page data, and the upper page data into one memory cell group MCG (time t36).

FIG. 10B illustrates an operation when a result that the number of error bits is equal to or smaller than the threshold value Thₑᵣᵣ₁ is obtained by the latch test operation. The same operation as FIG. 10A is executed until the time t33. At the time t33, the controller 200 causes the memory chip 100_0 to start a program operation of storing the lower page data, the middle page data, and the upper page data into one memory cell group MCG. Further, the controller 200, which causes the memory chip 100 to start the program operation, executes a data-out operation (Dout (Up)) of acquiring the upper page data that is latched by the latch circuit 120 and stored in the data register 111. The controller 200 executes error correction on the upper page data acquired by the data-out operation and determines the number of error bits. Then, the controller 200 compares the number of error bits with the threshold value Thₑᵣᵣ₁.

In the example of FIG. 10B, it is assumed that the number of error bits is equal to or smaller than the threshold value Thₑᵣᵣ₁. Therefore, the controller 200 causes the memory chip 100 to continue the program operation without executing the training operation (time t41).

In this manner, the controller 200 executes the latch test operation after the data-in operation of all the data to be written to the three pages is completed. As a result, the execution period of the data-out operation for the latch test operation can be overlapped with the period of time during which the program operation is executed. Thus, the time required for executing the latch test operation can be concealed by executing the program operation, and the efficiency of the latch test operation is further improved.

Note that, in the example illustrated in FIGS. 10A and 10B, the execution period of the data-out operation for the latch test operation is included in the period of time during which the program operation is executed. As long as the execution period of the data-out operation for the latch test operation partly overlaps with the execution period of time of the program operation, the execution timing of the latch test operation and the execution timing of the program operation are any execution timing.

In addition, in the example illustrated in FIGS. 10A and 10B, the upper page data among the three pieces of data to be written is used for the latch test operation. The data used in the latch test operation is not limited to the upper page data. As long as the controller 200 can acquire by the data-out operation, the controller 200 may use any one piece of data among the three pieces of data to be written for the latch test operation. The controller 200 may use only any one piece of data among the three pieces of data to be written for the latch test operation. The controller 200 may use only any two pieces of data among the three pieces of data to be written for the latch test operation. The controller 200 may use all of the three pieces of data to be written for the latch test operation.

### Second Embodiment

In a second embodiment, matters different from those in the first embodiment are described. Matters the same as those in the first embodiment are briefly described or are not described.

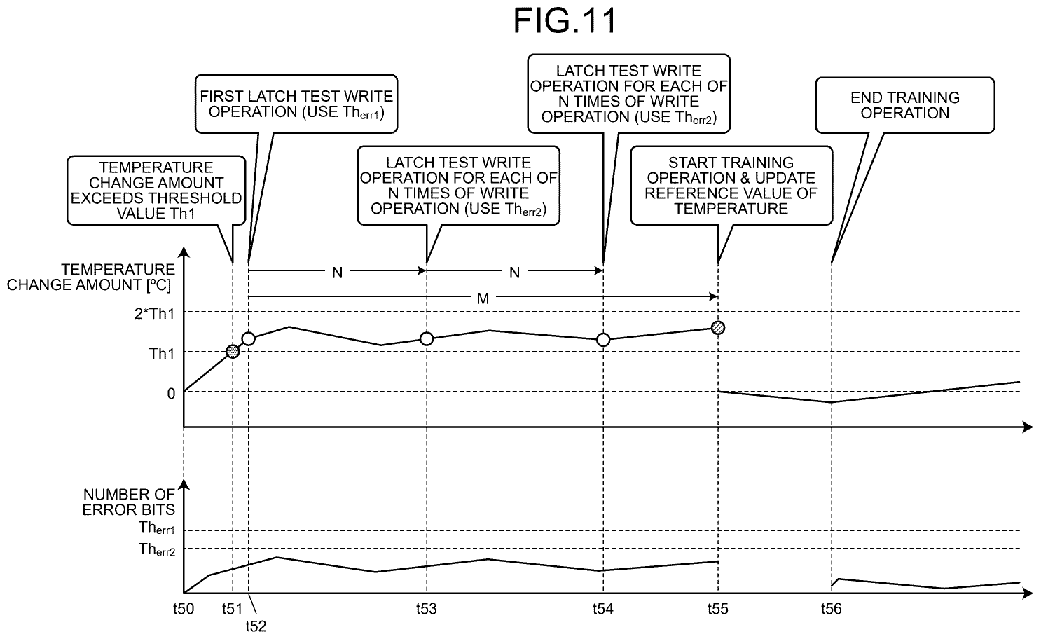

FIG. 11 is a diagram illustrating an example of a timing of a latch test write operation according to the second embodiment. FIG. 11 illustrates temporal transition of the temperature change amount and the number of error bits obtained when the latch test operation is executed.

In the example illustrated in FIG. 11, the reference value of the temperature is set (or updated) at time t50.

At time t51, the temperature change amount exceeds the threshold value Th1. In response to the temperature change amount exceeding the threshold value Th1, the controller 200 executes the latch test write operation in a write operation executed for the first time after the time t51, at which the temperature change amount exceeds the threshold value Th1 (time t52).

In the second embodiment, even if a result that the number of error bits is smaller than the threshold value Thₑᵣᵣ₁ is obtained in the first latch test write operation, and the training operation is skipped, the latch test write operation is executed at multiple different timings thereafter. As a result, it is possible to prevent the degree of error that occurs when data is latched by the latch circuit 120 from deviating from the allowable range after the first latch test write operation.

Specifically, in the example illustrated in FIG. 11, from times t53 and t54, the controller 200 executes the latch test write operation for each write operation of a predetermined number of times (denoted as N times). N is, for example, an integer of 2 or larger. N is set in advance. N may be settable from the host 2. Note that N is an example of a second set value.

The threshold value to be compared with the number of error bits may be the same or different among the first latch test write operation and the latch test write operation executed for each of N times of the write operation. Here, as an example, the threshold value Thₑᵣᵣ₁ is used in the first latch test write operation, and a threshold value Thₑᵣᵣ₂ smaller than the threshold value Thₑᵣᵣ₁ is used in the latch test write operation executed for each of N times of the write operation. Thus, in the latch test write operation executed for each of N times of the write operation, the training operation is executed more likely than in the first latch test write operation.

Further, during the operation in a state where the temperature change amount is large, even if the number of error bits obtained in the latch test operation does not reach the threshold values Thₑᵣᵣ₁ and Thₑᵣᵣ₂, the degree of error that occurs when data is latched by the latch circuit 120 transitions to a poor level. Therefore, when the operation in a state where the temperature change amount is large continues to some extent, the training operation and the update of the reference value of the temperature are forcibly executed.

Specifically, in the example illustrated in FIG. 11, when the write operation is executed a predetermined number of times (referred to as M times) after the temperature change amount exceeds the threshold value Th1, the controller 200 forcibly executes the training operation and the update of the reference value of the temperature (time t55). M is, for example, an integer of 2 or larger. M is set in advance. M may be settable from the host 2. Note that M is an example of a first set value.

At the time t55, the reference value of the temperature is updated, and thus the temperature change amount transitions to 0. When the training operation is completed (time t56), the number of error bits is suppressed as compared with the time t52 to the time t55, at each of which an operation is performed in a state where the temperature change amount is large.

Moreover, in the second embodiment, a threshold value Th2 may be provided in addition to the threshold value Th1 as a threshold value for the temperature change amount. The threshold value Th2 is larger than the threshold value Th1. When the temperature change amount reaches the threshold value Th2, the controller 200 forcibly executes the training operation and the update of the reference value of the temperature, regardless of the number of error bits. The threshold value Th2 is set in advance. The threshold value Th2 may be settable from the host 2. The threshold value Th2 is an example of a third threshold value. The controller 200 may not execute the training operation when the temperature change amount is equal to the threshold value Th2 and execute the training operation when the temperature change amount is larger than the threshold value Th2.

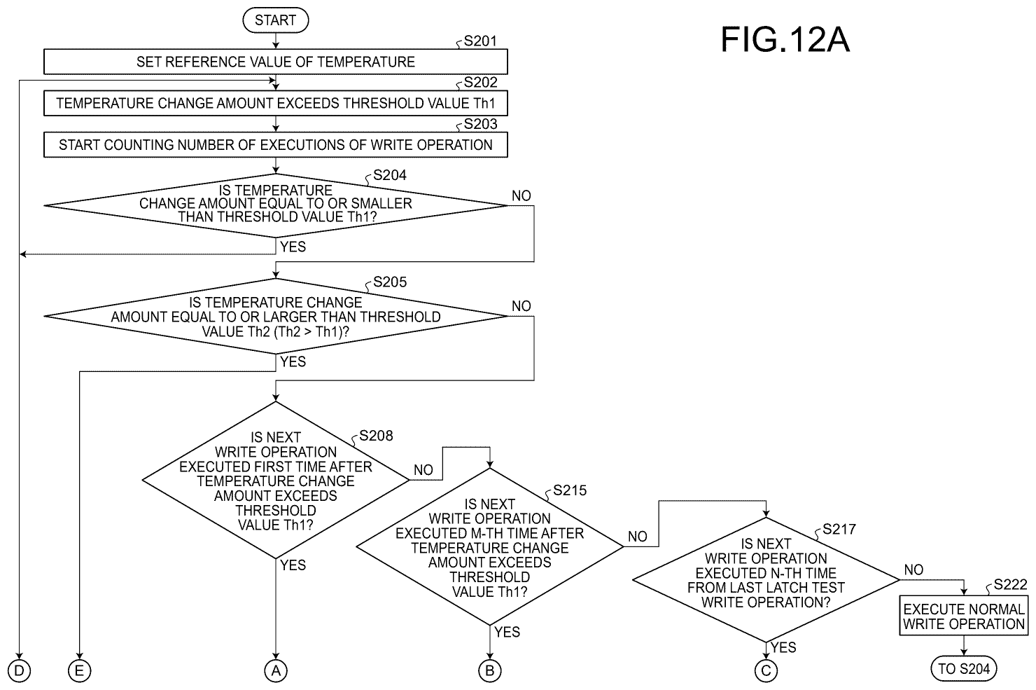

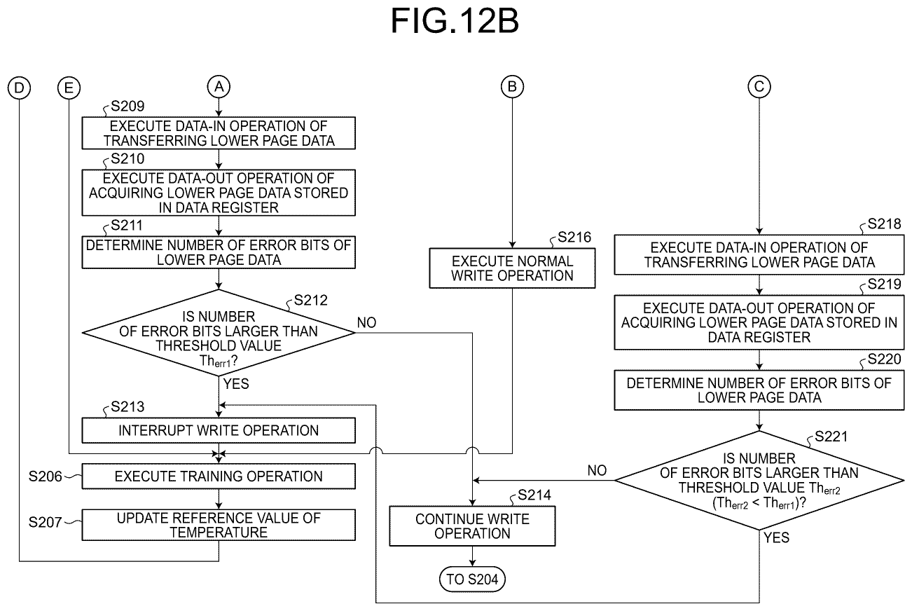

FIGS. 12A and 12B constitute a flowchart illustrating an example of an operation of the controller 200 according to the second embodiment. Note that, in FIGS. 12A and 12B, the read operation and the erase operation are not referred to. The read operation and the erase operation are normally executed. A series of operations shown by the pair of FIGS. 12A and 12B is executed for each memory chip 100.

First, in step S201, processing the same as that of step S101 illustrated in FIG. 8 is executed. That is, the controller 200 sets the reference value of temperature (S201). Then, the controller 200 monitors the temperature change amount and determines whether the temperature change amount exceeds the threshold value Th1.

When the temperature change amount exceeds the threshold value Th1 (S202), the controller 200 starts counting the number of executions of a write operation after the temperature change amount exceeds the threshold value Th1 (S203).

When the temperature change amount does not exceed the threshold value Th1, the controller 200 can execute a normal write operation as the write operation. Note that the processing when the temperature change amount reaches the threshold value Th1 but does not exceed the threshold value Th1 is not limited thereto. When the temperature change amount reaches the threshold value Th1, the control may transition to step S203.

Subsequently, the controller 200 determines whether the temperature change amount is equal to or smaller than the threshold value Th1 (S204). When the temperature change amount is equal to or smaller than the threshold value Th1 (S204: Yes), the controller 200 performs a normal operation until the temperature change amount exceeds the threshold value Th1 (S202).

When the temperature change amount is not equal to or smaller than the threshold value Th1 (S204: No), the controller 200 determines whether the temperature change amount is equal to or larger than the threshold value Th2 (S205).

When the temperature change amount is equal to or larger than the threshold value Th2 (S205: Yes), the controller 200 executes the training operation (S206). Along with the start of the training operation, in step S207, the controller 200 updates the reference value of the temperature change by a method similar to that in step S201, and the control transitions to step S202.

When the temperature change amount is not equal to or larger than the threshold value Th2 (S205: No), the controller 200 determines whether the write operation to be executed next is a write operation executed for the first time after the temperature change amount exceeds the threshold value Th1 (S208).

When the write operation to be executed next is a write operation executed for the first time after the temperature change amount exceeds the threshold value Th1 (S208: Yes), the controller 200 executes the latch test write operation.

The controller 200 first executes the data-in operation of transferring lower page data (S209). Then, in step S210, the controller 200 executes the data-out operation of acquiring the lower page data that is transferred to the memory chip 100 by the data-in operation and stored in the data register 111 of the memory chip 100. The controller 200 determines the number of error bits of the lower page data acquired from the memory chip 100 (S211). Then, the controller 200 compares the number of error bits with the threshold value Thₑᵣᵣ₁.

When the number of error bits is larger than the threshold value Thₑᵣᵣ₁ (S212: Yes), the controller 200 interrupts the write operation (S213), and the control transitions to step S206. That is, the controller 200 executes the training operation (S206).

When the number of error bits is not larger than the threshold value Thₑᵣᵣ₁ (S212: No), the controller 200 continues the write operation (S214), and the control transitions to step S204.

When the write operation to be executed next is not a write operation executed for the first time after the temperature change amount exceeds the threshold value Th1 (S208: No), the controller 200 determines whether the write operation to be executed next is the M-th write operation executed after the temperature change amount exceeds the threshold value Th1 (S215).

When the write operation to be executed next is the M-th write operation executed after the temperature change amount exceeds the threshold value Th1 (S215: Yes), the controller 200 executes the normal write operation (S216). Then, the control transitions to step S206. That is, the controller 200 executes the training operation (S206).

When the write operation to be executed next is not the M-th write operation executed after the temperature change amount exceeds the threshold value Th1 (S215: No), the controller 200 determines whether the write operation to be executed next is the N-th write operation from the last latch test write operation (S217).

When the write operation to be executed next is the N-th write operation from the last latch test write operation (S217: Yes), the controller 200 executes the latch test write operation. Note that, the threshold value Thₑᵣᵣ₂ is used instead of the threshold value Thₑᵣᵣ₁.

The controller 200 first executes the data-in operation of transferring lower page data (S218). Then, in step S219, the controller 200 executes the data-out operation of acquiring the lower page data that is transferred to the memory chip 100 by the data-in operation and stored in the data register 111 of the memory chip 100. The controller 200 determines the number of error bits of the lower page data acquired from the memory chip 100 (S220). Then, the controller 200 compares the number of error bits with the threshold value Thₑᵣᵣ₂.

When the number of error bits is larger than the threshold value Thₑᵣᵣ₂ (S221: Yes), the control transitions to step S213. That is, the controller 200 interrupts the write operation (S213) and executes the training operation (S206).

When the number of error bits is not larger than the threshold value Thₑᵣᵣ₂ (S221: No), the control transitions to step S214. That is, the controller 200 continues the write operation (S214).

When the write operation to be executed next is not the N-th write operation from the last latch test write operation (S217: No), the controller 200 executes the normal write operation as the next write operation (S222). Then, the control transitions to step S204.

Note that in the example illustrated in FIGS. 12A and 12B, the lower page data is used in the latch test operation. The data used in the latch test operation is not limited to the lower page data. For example, the modification of the first embodiment is also applicable to the second embodiment.

As described above, according to the second embodiment, the controller 200 executes the training operation when the write operation is executed M times after the temperature change amount exceeds the threshold value Th1.

During the operation in a state where the temperature change amount is large, the degree of error that occurs when data is latched by the latch circuit 120 transitions to a poor level. By the controller 200 forcibly executing the training operation when the write operation is executed M times, it is possible to reduce the degree of error that occurs when data is latched by the latch circuit 120.

In addition, according to the second embodiment, the controller 200 executes the latch test write operation for each of N times of the write operation.

Accordingly, the degree of error that occurs when data is latched by the latch circuit 120 is prevented from deviating from the allowable range after the first latch test write operation.

In addition, according to the second embodiment, the threshold value Thₑᵣᵣ₂ used in the latch test write operation executed for each of N times of the write operation is smaller than the threshold value Thₑᵣᵣ₁ used in the first latch test write operation.

Therefore, in the latch test write operation after the first latch test write operation, it is possible to determine whether to execute the training operation with a determination criterion stricter than that of the first latch test write operation.

Moreover, according to the second embodiment, the controller 200 executes the training operation when the temperature change amount is larger than the threshold value Th2.

In the first embodiment, the second embodiment, and the modifications, the controller 200 executes the latch test write operation when the temperature change amount exceeds the threshold value Th1. The trigger of the latch test write operation is not limited thereto. For example, the delay time in the delay circuit 123 can also vary due to a variation in the voltage of the power supplied to the memory chip 100.

Therefore, the controller 200 may execute the latch test write operation by a trigger based on the voltage of the power supplied to the memory chip 100.

In addition, an example of the trigger of the execution of the latch test write operation based on the temperature change amount is specifically described with reference to FIG. 8 and FIGS. 12A and 12B. The trigger of the latch test write operation based on the temperature change amount is not limited to these examples.

In addition, in the latch test operation, the controller 200 acquires the data stored in the data register 111 by the data-out operation and performs error correction with the ECC circuit 206 on the acquired data to determine the number of error bits.

The method of determining the number of error bits is not limited to the method using the ECC circuit 206. For example, when performing the data-in operation, the controller 200 stores a copy of data for performing the data-in operation, for example, in the RAM 202 or the like in advance. Then, in the latch test operation, the controller 200 may acquire the data stored in the data register 111 by the data-out operation and compare the acquired data with the copy stored in the RAM 202 to determine the number of error bits.

As described above in the first embodiment, the second embodiment, and the modifications, the controller 200 can execute any write operation of the normal write operation and the latch test write operation.

By the latch test write operation, the efficiency of the latch test operation for determining whether to execute the training operation is improved, and the execution frequency of the training operation can be suppressed. Therefore, performance decrease caused by the training operation is suppressed.

While certain embodiments have been described, these embodiments have been presented by way of example only, and are not intended to limit the scope of the inventions. Indeed, the novel embodiments described herein may be embodied in a variety of other forms; moreover, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A memory system comprising:
a memory device including:
a first terminal to which a data signal is input;
a second terminal to which a data strobe signal is input;
a latch circuit configured to latch, based on the data strobe signal, first data or second data from the data signal;
a delay circuit connected between the second terminal and the latch circuit;
a memory cell array, and
a buffer circuit connected between the memory cell array and the latch circuit; and
a controller connected to the memory device via the first terminal and the second terminal and capable of executing a first write operation and executing a second write operation, the controller being configured to:
in the first write operation,
transfer the first data to be written to the memory device by using the data signal and the data strobe signal; and
cause the memory device to store the first data into the memory cell array, and,
in the second write operation,
transfer the second data to be written to the memory device by using the data signal and the data strobe signal, the second data being stored in the buffer circuit after being latched by the latch circuit;
acquire the second data from the buffer circuit;
determine the number of error bits included in the acquired second data;
execute a training operation of adjusting delay time of the delay circuit when the number of error bits is larger than a first threshold value; and
cause the memory device to store, into the memory cell array, the second data having been stored in the buffer circuit, without executing the training operation when the number of error bits is smaller than the first threshold value.

2. The memory system according to claim 1, wherein
the controller is further configured to:
in the second write operation, cause the memory device to store, into the memory cell array, the second data having been stored in the buffer circuit, without executing the transfer of the second data to the memory device again when the number of error bits is smaller than the first threshold value.

3. The memory system according to claim 1, further comprising a temperature sensor, wherein
the controller is further configured to:
monitor a temperature change amount from a reference value based on a detected value of a temperature output by the temperature sensor;
determine, based on the temperature change amount, which one of the first write operation or the second write operation is to be executed; and
update the reference value according to execution of the training operation.

4. The memory system according to claim 1, further comprising a temperature sensor, wherein
the controller is further configured to:
monitor a temperature change amount from a reference value based on a detected value of a temperature output by the temperature sensor;
execute the first write operation when the temperature change amount is smaller than a second threshold value;
when the temperature change amount exceeds the second threshold value, execute the second write operation in a write operation executed for the first time after the temperature change amount exceeds the second threshold value; and
update the reference value according to execution of the training operation.

5. The memory system according to claim 4, wherein
the controller is further configured to:
execute the training operation when the number of times of a write operation executed after the temperature change amount exceeds the second threshold value reaches a first set value.

6. The memory system according to claim 4, wherein
the controller is further configured to:
execute the second write operation every time the number of times of a write operation executed after the second write operation is executed reaches a second set value.

7. The memory system according to claim 6, wherein
a value as the first threshold value, which is used in the second write operation executed every time the number of times of the write operation executed after the second write operation is executed reaches the second set value, is smaller than a value as the first threshold value used in the second write operation executed in the write operation executed for the first time after the temperature change amount exceeds the second threshold value.

8. The memory system according to claim 4, wherein
the controller is further configured to:
execute the training operation when the temperature change amount is larger than a third threshold value, the third threshold value being larger than the second threshold value.

9. The memory system according to claim 1, wherein
the controller is further configured to:
in the second write operation, acquire at least part of the second data in a period of time at least partly overlapping with a period of time during which the memory device stores the second data into the memory cell array.

10. The memory system according to claim 1, wherein
the memory cell array includes a plurality of memory cell groups, and
each of the plurality of memory cell groups includes a first page and a second page,
the second data includes third data to be written into the first page and fourth data to be written into the second page, and
the controller is configured to, in the second write operation:
acquire only the third data among the third data and the fourth data included in the second data from the buffer circuit; and
determine the number of error bits included in the acquired third data.

11. A method of controlling a memory device, the memory device including a first terminal to which a data signal is input and a second terminal to which a data strobe signal is input, a latch circuit configured to latch, based on the data strobe signal, first data or second data from the data signal, a delay circuit connected between the second terminal and the latch circuit, a memory cell array, and a buffer circuit connected between the memory cell array and the latch circuit, the method comprising:
executing a first write operation on the memory device; and
executing a second write operation on the memory device, wherein the first write operation includes:
transferring the first data to be written to the memory device by using the data signal and the data strobe signal; and
causing the memory device to store the first data into the memory cell array, and
the second write operation includes:
transferring the second data to be written to the memory device by using the data signal and the data strobe signal, the second data being stored in the buffer circuit after being latched by the latch circuit;
acquiring the second data from the buffer circuit;
determining the number of error bits included in the acquired second data;
executing a training operation of adjusting delay time of the delay circuit when the number of error bits is larger than a first threshold value; and
causing the memory device to store, into the memory cell array, the second data having been stored in the buffer circuit, without executing the training operation when the number of error bits is smaller than the first threshold value.

12. The method according to claim 11, wherein
the second write operation further includes:
causing the memory device to store, into the memory cell array, the second data having been stored in the buffer circuit, without executing the transfer of the second data to the memory device again when the number of error bits is smaller than the first threshold value.

13. The method according to claim 11, further comprising:
monitoring a temperature change amount from a reference value based on a detected value of a temperature output by a temperature sensor;
determining, based on the temperature change amount, which one of the first write operation or the second write operation is to be executed; and
updating the reference value according to execution of the training operation.

14. The method according to claim 11, further comprising:
monitoring a temperature change amount from a reference value based on a detected value of a temperature output by a temperature sensor;
executing the first write operation when the temperature change amount is smaller than a second threshold value;
when the temperature change amount exceeds the second threshold value, executing the second write operation in a write operation executed for the first time after the temperature change amount exceeds the second threshold value; and
updating the reference value according to execution of the training operation.

15. The method according to claim 14, further comprising:
executing the training operation when the number of times of a write operation executed after the temperature change amount exceeds the second threshold value reaches a first set value.

16. The method according to claim 14, further comprising:
executing the second write operation every time the number of times of a write operation executed after the second write operation is executed reaches a second set value.

17. The method according to claim 16, wherein
a value as the first threshold value, which is used in the second write operation executed every time the number of times of the write operation executed after the second write operation is executed reaches the second set value, is smaller than a value as the first threshold value used in the second write operation executed in the write operation executed for the first time after the temperature change amount exceeds the second threshold value.

18. The method of claim 14, further comprising:
executing the training operation when the temperature change amount is larger than a third threshold value, the third threshold value being larger than the second threshold value.

19. The method according to claim 11, wherein
the second write operation further includes:
acquiring at least part of the second data in a period of time at least partly overlapping with a period of time during which the memory device stores the second data into the memory cell array.

20. The method according to claim 11, wherein
the memory cell array includes a plurality of memory cell groups, and
each of the plurality of memory cell groups includes a first page and a second page,
the second data includes third data to be written into the first page and fourth data to be written into the second page, and
in the second write operation,
only the third data is acquired, among the third data and the fourth data included in the second data from the buffer circuit, and
the number of error bits included in the acquired third data is determined.
